(19) United States
(12) Patent Application Publication
(10) Pub. No.: US 2005/0263873 A1
(43) Pub. Date: Dec. 1, 2005

(54) Interposer substrate, semiconductor package and semiconductor device, and their producing methods

(75) Inventor: Hiroyuki Shoji, Kawasaki-Shi (JP)

Correspondence Address: YOUNG & THOMPSON, 745 SOUTH 23RD STREET, 2ND FLOOR, ARLINGTON, VA, 22202, US

(73) Assignee: NEC COMPOUND SEMICONDUCTOR DEVICE, LTD., KAWASAKI-SHI (JP)

(21) Appl. No.: 11/139,584

(22) Filed: May 31, 2005

(30) Foreign Application Priority Data
May 28, 2004 (JP) 2004-159767

(51) Int. Cl. H01L 21/48; H01L 23/52

(52) U.S. Cl. 257/698; 257/676; 438/123; 257/700; 257/692; 257/784; 438/617

(57) ABSTRACT

A semiconductor package comprises a semiconductor chip, an interposer substrate, a plurality of unfilled end face through holes arrayed at the periphery of the semiconductor package, a plurality of inner through holes, a plurality of end face through hole electrodes each formed inside the end face through holes so as to be exposed on a side face of the semiconductor package and a plurality of inner electrodes each formed around openings of the inner through holes on the other side of the interposer substrate, the semiconductor chip being mounted on one side of the interposer substrate, the electrodes being laid out in an array on the other side of the interposer substrate.

### FIELD OF THE INVENTION

The present invention relates to an interposer substrate, semiconductor package and semiconductor device, and methods for producing same.

### BACKGROUND OF THE INVENTION

A semiconductor package around which a plurality of electrodes are laid out is known as described in Japanese Patent Kokai Publication No. JP-P2001-339002A.

Miniaturization of a semiconductor package is one of important factors. Therefore, there is an LGA (Land-Grid-Array) type of a semiconductor package of which a plurality of electrodes are laid out in an array on the back face.

[Patent Document 1]

Japanese Patent Kokai Publication No. JP-P2001-339002A
   [Patent Document 2]
Japanese Patent Kokai Publication No. JP-A-8-236898

### SUMMARY OF THE DISCLOSURE

The peripheral array type of semiconductor package as described in Japanese Patent Kokai Publication No. JP-P2001-339002A is unsuitable for miniaturization of the package because electrodes are arrayed only around the package.

On the other hand, in the LGA (Land-Grid-Array) type of semiconductor package in which a plurality of electrodes are laid out in an array, as described in Japanese Patent Kokai Publication No. JP-A-8-236898, outer electrodes of the package are only metal patterns laid out on the back face of the package, so that there is a problem that a fillet of mounting solder can not be formed. This provides problems that warp of a substrate caused by heat generated the upon mounting generates stress which causes failure in mounting, and that fall impact brings about defects of the package easily.

The electrodes are arrayed only on the back face of the semiconductor package, so there is also a problem that the mounting state of the semiconductor package can not be checked by an inspection of an external appearance after the mounting. Even if this semiconductor package is x-rayed and the obtained transmission picture is checked, there finally remains a problem that it is difficult to examine whether the actual mounting quality is good or bad because the fillet of the mounting solder is not formed.

There is much desired in the art for a semiconductor package, which is miniaturized, which is easy to examine the state of the mounting, and which has high strength of the mounting, an interposer substrate for the semiconductor package, and a semiconductor device in which the semiconductor package is mounted, and their producing methods.

In a first aspect, the present invention provides an interposer substrate, in which a plurality of semiconductor chips are mounted on one side of the interposer substrate, each plurality of product patterns are laid out in an array on the other side of the interposer substrate, and a divided part of the interposer substrate is used as a component of a semiconductor package. The interposer substrate comprises: a plurality of unfilled outer through holes, which are arrayed at predetermined positions so as to serve as end face through holes arrayed at a periphery of the semiconductor package when the semiconductor package is formed; a plurality of inner through holes, which are arrayed at an area surrounded by the outer through holes so as to serve as through holes arrayed at an inside of the semiconductor package when the semiconductor package is formed; a plurality of first electrodes, which are each formed inside the outer through holes so as to serve as end face through hole electrodes exposed on a side face of the semiconductor package when the interposer substrate is cut across the outer through holes; and a plurality of second electrodes, which are each formed around openings of the inner through holes on the other side of the interposer substrate so as to serve as inner electrodes of the semiconductor package.

In a second aspect, the present invention provides a semiconductor package comprising: a semiconductor chip; an interposer substrate; a plurality of electrodes; a plurality of unfilled end face through holes; and a plurality of inner through holes. The semiconductor chip is mounted on one side of the interposer substrate. The electrodes are laid out in an array on the other side of the interposer substrate. The unfilled end face through holes are arrayed at the periphery of the semiconductor package. The inner through holes are arrayed at an inner area of the semiconductor package. A plurality of end face through hole electrodes of the electrodes are each formed inside the end face through holes so as to be exposed on a side face of the semiconductor package. A plurality of inner electrodes of the electrodes are each formed around openings of the inner through holes on the other side of the interposer substrate.

In a third aspect, the present invention provides a semiconductor device comprising: a semiconductor package comprising a semiconductor chip and an interposer substrate, the semiconductor chip being mounted on one side of the interposer substrate, a plurality of electrodes being laid out in an array on the other side of the interposer substrate; a mounting substrate for mounting the semiconductor package. The semiconductor device further comprises a plurality of unfilled end face through holes arrayed at the periphery of the semiconductor package; a plurality of inner through holes arrayed at an inner area of the semiconductor package; a plurality of end face through hole electrodes, which are each formed inside the end face through holes so as to be exposed on a side face of the semiconductor package; a plurality of inner electrodes, which are each formed around openings of the inner through holes on the other side of the interposer substrate; and a solder fillet formed between the end face through hole electrode and the mounting substrate on a side part of the semiconductor package.

In a fourth aspect, the present invention provides a method for producing an interposer substrate wherein a plurality of semiconductor chips are mounted on one side of the interposer substrate, a plurality of product patterns are laid out in an array on the other side of the interposer substrate, and the interposer substrate serves as a component of a semiconductor package by dividing into pieces. The method comprises the steps of: forming a plurality of penetration holes in a base material, of which electrically conductive layers are formed on both the sides, by mechanical processing; forming a plurality of non-penetration holes around the penetration holes in the base material by laser processing; forming first electrodes at least inside the non-penetration holes by plating the penetration holes and non-penetration holes, and dicing and dividing the non-penetration holes so as to serve as end face through hole electrodes of the semiconductor package; forming a plurality of at least second electrodes in an array on the base material by etching the electrically conductive layer; and filling the plated penetration holes or sealing openings of the penetration holes at least on one side of the interposer substrate.

In a fifth aspect, the present invention provides a method for producing a semiconductor package; the semiconductor package having a plurality of semiconductor chips and an interposer substrate, the interposer substrate serving as a component of the semiconductor package by mounting the semiconductor chips on one side of the interposer substrate, laying out a plurality of electrodes in an array on the other side of the interposer substrate and dividing the interposer substrate into pieces. The interposer substrate comprises; a plurality of unfilled outer through holes arrayed at predetermined positions, a plurality of inner through holes, which are arrayed at an area surrounded by the outer through holes, and which are filled or whose openings are sealed at least on one side of the interposer substrate, a plurality of first electrodes, which are each formed inside the outer through holes so as to serve as end face through hole electrodes exposed on a side face of the semiconductor package, a plurality of outer electrodes, which are each formed around openings of the outer through holes on the other side of the interposer substrate, and a plurality of second electrodes, which are each formed around openings of the inner through holes on the other side of the interposer substrate so as to serve as inner electrodes of the semiconductor package. The method uses the interposer substrate. The method comprises the steps of: providing the interposer substrate; mounting the semiconductor chips on the one side of the interposer substrate; connecting the semiconductor chips with the interposer substrate electrically; sealing the semiconductor chips on the interposer substrate; and forming the end face through hole electrodes exposed on the side face of the divided semiconductor package, by dicing the interposer substrate across the outer through holes, and dividing the semiconductor package into pieces so as to serve the outer through holes of the interposer substrate as the end face through holes of the divided semiconductor package.

In a sixth aspect, the present invention provides a method for producing a semiconductor device. The semiconductor device comprises a semiconductor package and a mounting substrate for mounting the semiconductor package. The semiconductor package comprises; a semiconductor chip, an interposer substrate, the semiconductor chip being mounted on one side of the interposer substrate, a plurality of electrodes being laid out in an array on the other side of the interposer substrate, a plurality of unfilled end face through holes, which are each arrayed at the periphery of the semiconductor package, a plurality of inner through holes, which are each arrayed in an inner area of the semiconductor package, a plurality of end face through hole electrodes of the electrodes, which are each formed inside the end face through holes so as to be exposed on a side face of the semiconductor package, a plurality of outer electrodes, which are each formed around openings of the end face through holes on the other side of the interposer substrate, and a plurality of inner electrodes, which are each formed around openings of the inner through holes on the other side of the interposer substrate. The method uses the semiconductor package. The method comprises the steps of; providing the semiconductor package; forming a solder fillet between the end face through hole electrode and the mounting substrate in the side face of the semiconductor package when the other side of the interposer substrate is soldered on the mounting substrate to mount the semiconductor package on the mounting substrate.

The meritorious effects of the present invention are summarized as follows.

The present invention can provide the semiconductor package which meets requirements of both miniaturization and high mounting effect and the method for producing the semiconductor package. Particularly, according to the present invention, a solder fillet can be formed on a side face (an end face) of the semiconductor package, which can be observed from the outside, in a mounting time by disposing a side face through hole electrode, which is exposed in the side face of the semiconductor package, at an outer part (the circumference, the periphery or the side face) of the semiconductor package. The present invention therefore has an effect that greater mounting strength, which a conventional LGA package does not have, can be achieved. For example, the present invention can keep the connection even if warp of the substrate caused by heat upon mounting generates stress. The present invention also can provide an effect that examination of the mounting state from an external appearance becomes easy, whereas such examination is difficult in the conventional LGA package of which a plurality of electrodes are arrayed on the back face but not exposed on the side face. According to the present invention, the semiconductor package can be miniaturized by laying out in an array a plurality of electrodes on the back face (the inner part) of the semiconductor package.

Accordingly, when the semiconductor package of the present invention is mounted on the mounting substrate, the solder fillet is formed on the side face of the semiconductor package, thereby providing the semiconductor device having greater strength.

The present invention can also provide the interposer substrate suitable for manufacture of the semiconductor package. The interposer substrate according to the present invention has a plurality of unfilled outer through holes which are arrayed at predetermined positions so as to serve as end face through holes arrayed along the periphery of the semiconductor package upon formation of the semiconductor package. After a plurality of semiconductor chips are mounted, the interposer substrate is diced so as to divide these outer side through holes to individuate the semiconductor chips, thereby producing the semiconductor package of the present invention efficiently.

### BRIEF DESCRIPTION OF THE DRAWINGS

FIG. 1 is a figure to explain a structure of a back face and side face (end face) of a semiconductor package in one embodiment according to the present invention.

FIG. 2 is a figure to explain a structure of the cross section along the line A-A′ in FIG. 1.

FIGS. 3A,3B,3C and 3D are a process chart to explain an assembly flow of a semiconductor package in one embodiment according to the present invention.

FIG. 4 is a cross sectional view to explain a structure of a semiconductor device in which a semiconductor package of one embodiment according to the present invention is mounted.

FIG. 5 is a cross sectional view to explain a structure of a semiconductor device in which a semiconductor package of a comparative example is mounted.

FIG. 6 is a figure to explain a method for making an unfilled through hole of an interposer substrate, which serves as an end face through hole of a semiconductor package of one embodiment according to the present invention, and an electrode around the through hole.

FIG. 7 is a figure to explain a method for making a filled through hole of an interposer substrate, which serves as an inner through hole of a semiconductor package of one embodiment according to the present invention, and an electrode around the through hole.

FIG. 8 is a figure to explain a method for making a through hole whose opening is sealed on one side of an interposer substrate and which serves as an inner through hole of a semiconductor package of another embodiment according to the present invention, and an electrode around the through hole.

### PREFERRED EMBODIMENTS OF THE INVENTION

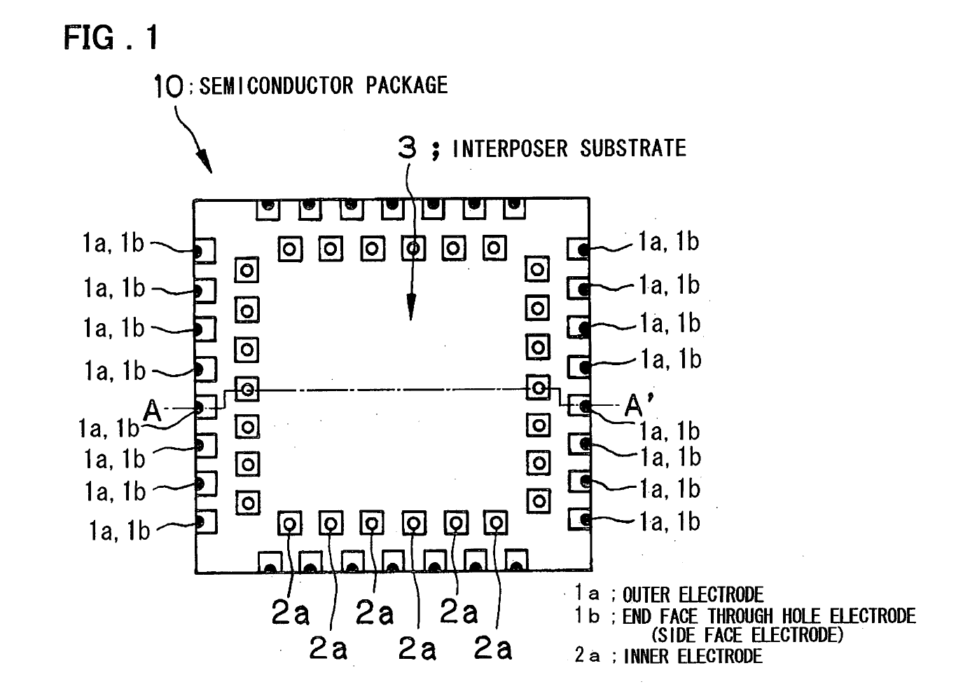

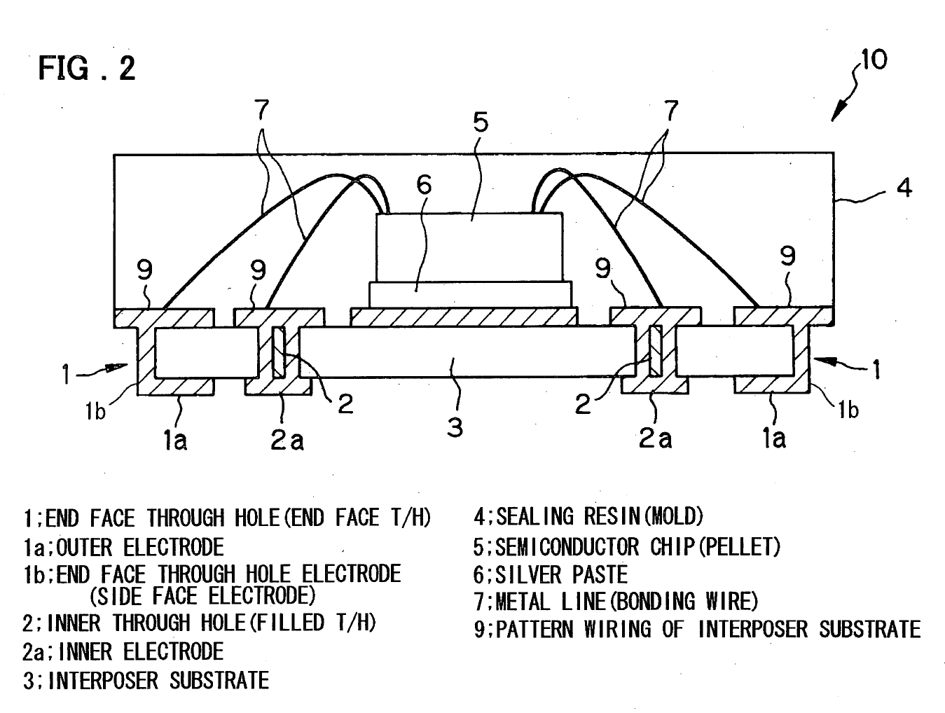

In a semiconductor package of a preferred embodiment according to the present invention, as shown in FIGS. 1 and 2, unfilled end face through holes formed by non-penetration laser via processing or other processing are arrayed at an outer part (the periphery or circumference) of the semiconductor package; through holes filled with a filling resin are arrayed at an inner part of the semiconductor package (on the inner side on the back face of the semiconductor package); end face through hole electrodes are arrayed on a side face of the semiconductor package; a plurality of electrodes (outer electrodes) are arrayed at an outer part (the periphery) on the back face of the semiconductor package; and a plurality of electrodes (inner electrodes) are arrayed at an inner part on the back face of the semiconductor package.

This semiconductor package can be efficiently produced by dicing an interposer substrate, which comprises a plurality of unfilled outer through holes and a plurality of inner through holes arrayed in an area surrounded by the outer through holes, across the outer through holes so as to divide the outer through holes. Electrodes formed inside the outer through holes (on the inner walls of the outer through holes) in the interposer substrate by plating or so like can serve as the end face through hole electrodes of the semiconductor package.

When the interposer substrate having single layer wirings on both the sides is used and the interposer substrate is thick, for example, the interposer substrate is 0.10-0.20 mm or 0.15 mm or over in thickness, in the steps of making the outer through holes of the interposer substrate, which serve as the end face through holes of the semiconductor package, by the non-penetration laser via processing and then forming the electrodes inside the through holes, openings of the non-penetration laser via holes are preferably extended, keeping a distance between the electrodes narrow, for example, by making horizontally sectional shapes of the non-penetration laser via holes not true circle but ellipse in order to improve electroless plating.

When it is necessary to cut the through holes, which are formed in the interposer substrate that is thin, for example, less than 0.15 mm in thickness, and which are filled with the filling resin, a warp of the substrate often causes a defect of conveyance because of the thickness of the substrate. In order to prevent such a defect, it is preferred that the openings of the inner through holes of the interposer substrate, which serve as inner through holes on the back face of the semiconductor package, are closed (sealed) with a resist film at least at one side of the interposer substrate, rather than that the inner through holes are filled with resin.

It is possible to suitably produce the interposer substrate having both the unfilled through hole and the filled through hole or the interposer substrate having both the unfilled through hole and the shut through hole, which is considered to be difficult, by selecting these methods corresponding to the thickness of the interposer substrate.

According to a preferred embodiment of the present invention, in the semiconductor package of, for example, LGA (Land-Grid-Array) in which a plurality of electrodes are arrayed in an array on the back face of the semiconductor package, a plurality of end face through holes are arrayed at (and along) only the outermost part and the end face through hole electrodes (side face electrodes) which are exposed on the side face (or end face) of the semiconductor package are formed on the inside (or inner wall) of the end face through holes.

According to a preferred embodiment of the present invention, in the semiconductor package having a package structure like LGA, formed by the steps of arraying a plurality of through hole electrodes on the back face of the interposer substrate (wiring substrate), mounting a semiconductor chip on the top face of the interposer substrate, connecting a pad on the semiconductor chip with a wiring pattern on the substrate through a metal wire, and sealing the semiconductor chip and so on with a resin, a plurality of end face through hole electrodes are arrayed at the outermost part of the semiconductor package so as to expose the electrodes on the side face of the semiconductor package.

According to a preferred embodiment of the present invention, when one side (surface, or the other side) of the interposer substrate is soldered on a mounting substrate to mount the semiconductor package on the mounting substrate, a solder fillet is formed between the end face through hole electrodes and the mounting substrate.

According to a preferred embodiment of the present invention, the inner through holes are filled with a resin.

According to a preferred embodiment of the present invention, openings of the inner through holes are sealed at least at one side of the interposer substrate.

According to a preferred embodiment of the present invention, transverse cross sections of the outer through holes are ellipse in shape.

### EXAMPLE 1

In order to explain the present invention in more detail, an example of the present invention is explained below referring to attached drawings.

FIG. 1 is a figure to explain a structure of the back face and side face (end face) of a semiconductor package according to an example of the present invention. FIG. 2 is a figure to explain a structure along the section A-A′ in FIG. 1.

Referring to FIG. 1, a semiconductor package 10 according to the example of the present invention, which is a package of an LGA type, has a plurality of outer electrodes (back face electrodes of end face through holes) 1a arrayed at an outer part and a plurality of inner electrodes (back face electrodes of inner through holes) 2a arrayed at an inner part on the back face of the semiconductor package (the back face of an interposer substrate 3), and also has a plurality of end face through hole electrodes (side face electrodes) 1b on the side face (end face) of the semiconductor package.

Referring to FIG. 2, the structure of the semiconductor package shown in FIG. 1 is explained in further detail. The semiconductor package 10 has a semiconductor chip 5 and the interposer substrate 3 of which the semiconductor chip 5 is mounted on one side (top face) and of which a plurality of electrodes 1a, 2a are laid out in arrays on the other side (back face). The semiconductor chip 5 is mounted on the top face of the interposer substrate 3 through a silver paste 6, electrodes on the semiconductor chip 5 are electrically connected with pattern wirings 9 through metal lines (bonding wires) 7, and the semiconductor chip 5 is molded (sealed) on the interposer substrate 3 with a sealing resin 4.

The semiconductor package 10 also has a plurality of unfilled end face through holes 1 arrayed at the periphery of the semiconductor package 10, a plurality of inner through holes 2 arrayed at an inner area of the semiconductor package 10, a plurality of end face through hole electrodes 1b which are each formed inside the end face through holes 1 and exposed on the side face of the semiconductor package 10, a plurality of outer electrodes 1a each formed around openings of the end face through holes 1 on the back face of the interposer substrate 3, and a plurality of inner electrodes 2a each formed around openings of the inner through holes 2. In this way, it is possible to miniaturize the semiconductor package 10 because many electrodes are arrayed in the array.

The pattern wiring 9, formed from, for example, copper foil, on the interposer substrate is electrically connected with the outer electrodes 1a, the inner electrodes 2a and side face electrodes 1b, respectively, through a plating layer, formed of conductive material, for example, a plating layer of copper, nickel and gold, in a predetermined through hole.

When the semiconductor package 10 is mounted, a solder fillet (side fillet) described below is formed between a plurality of end face through hole electrodes (side face electrodes) 1b and a mounting substrate.

Next, an example of a method for producing the semiconductor package having the structure described above is explained.

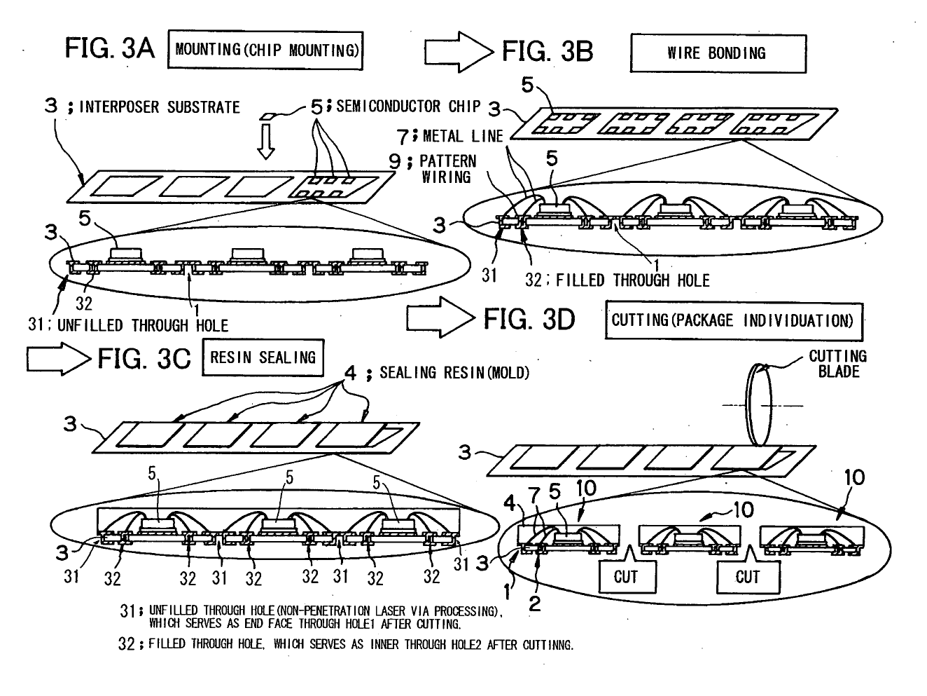

FIGS. 3A-3D are process chart to explain an assembling flow of the semiconductor package according to the example of the present invention.

Referring to a mounting (chip mounting) step in FIG. 3A, a plurality of semiconductor chips 5 are mounted on the interposer substrate 3 in which various through holes as described below are formed and in which a plurality of product patterns including bonding patterns are laid out in an array.

A plurality of patterns including a plurality of unfilled through holes (outer through holes) 31 arrayed at an outer area and a plurality of filled through holes (inner through holes) 32 arrayed at an area surrounded by the unfilled through holes 31 are laid out on the interposer substrate 3. The unfilled through holes (outer through holes) 31 serve as the end face through holes of the semiconductor package; the filled through holes 32 serve as the inner through holes of the semiconductor package; the internal electrodes of the unfilled through holes 31 serve as the end face through hole electrodes (side face electrodes) of the semiconductor package; the electrodes around the openings of the unfilled through holes 31 on the back face of the interposer substrate 3 serve as the outer electrodes of the semiconductor package; and the electrodes around the openings of the filled through holes 32 serve as the inner electrodes of the semiconductor package.

Then, referring to a wire bonding step in FIG. 3B, the semiconductor chips 5 are connected with the pattern wirings 9 on the top face of the interposer substrate 3 through the metal lines 7.

Then, referring to a resin sealing step in FIG. 3C, a plurality of semiconductor chips 5 are molded (sealed) together in a lump on the interposer substrate 3 by the sealing resin 4.

Now, referring to FIG. 3D, the interposer substrate 3 on which a plurality of semiconductor chips 5 are sealed are cut into pieces by a dicer or other means and are divided into individual packages to produce semiconductor packages. In this case, the interposer substrate 3 is cut (diced) across a plurality of unfilled through holes (outer through holes) 31. Therefore, the unfilled through holes 31 which are divided become the end face through holes 1 of the semiconductor package 10, and the filled through holes 32 become the inner through holes 2 of the semiconductor package 10.

Next, the mounted state of the semiconductor package produced as described above according to the example of the present invention is explained comparing with a comparative example.

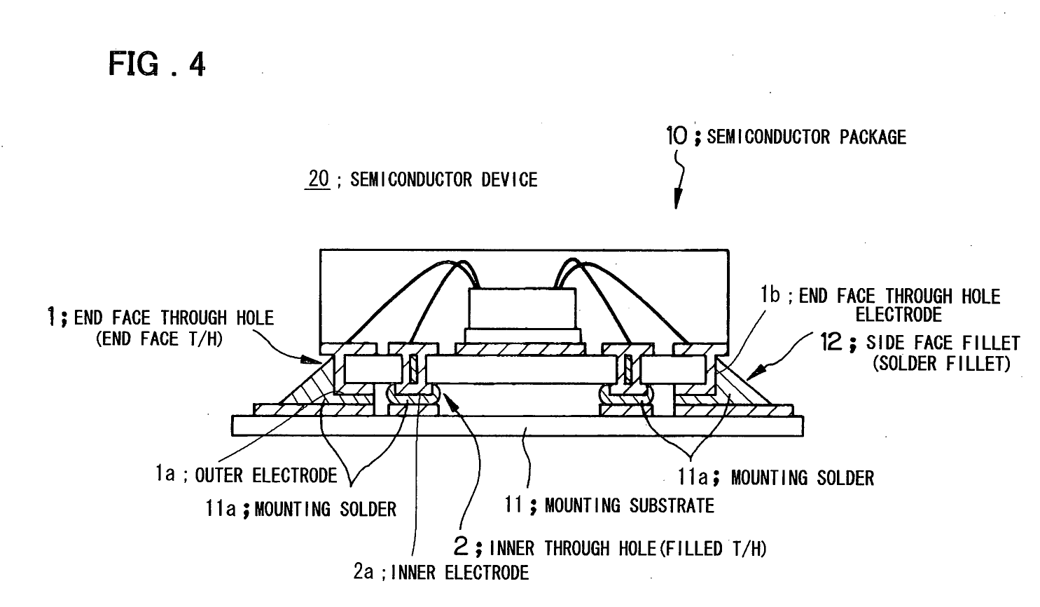

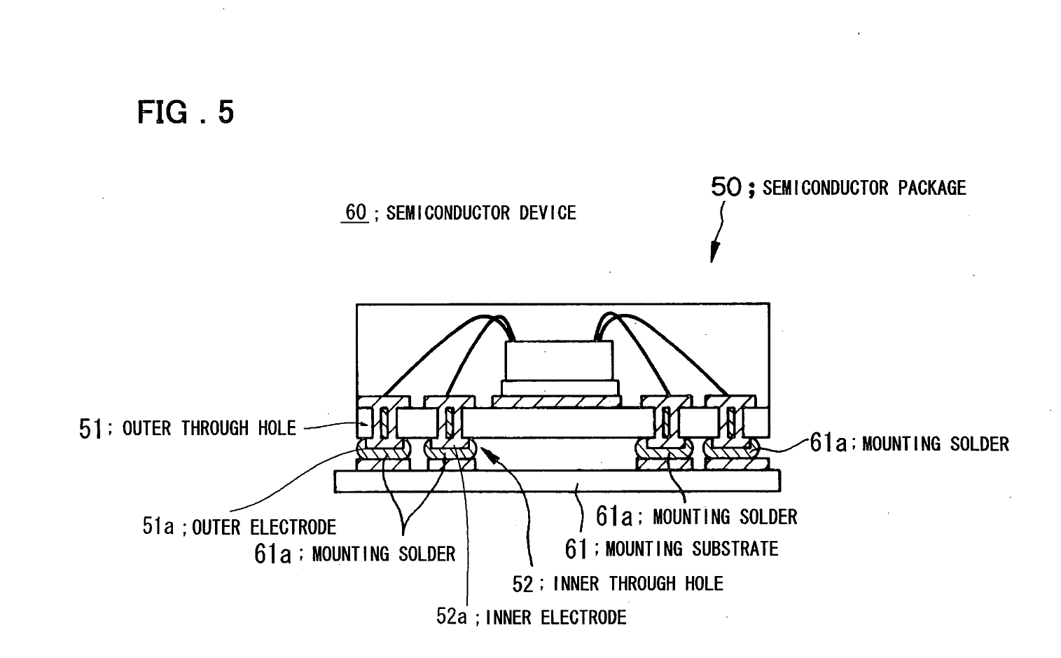

FIG. 4 is a cross sectional view to explain a structure of a semiconductor device in which the semiconductor package according to the example of the present invention is mounted. FIG. 5 is a cross sectional view to explain a structure of a semiconductor device in which a semiconductor package according to the comparative example is mounted. The semiconductor package according to the comparative example does not have the end face through hole electrodes.

Referring to FIG. 4, the semiconductor 10 according to the example of the present invention has, on the back side of the package, the outer electrodes 1a formed around the openings of the end face through holes 1 and the inner electrodes 2a formed around the openings of the inner through holes 2, and also has, inside the end face through holes 1, the end face through hole electrodes (side face electrodes) 1b formed so as to be exposed on the side face of the package. Therefore, when the semiconductor package 10 is mounted on the mounting substrate 11 by a mounting solder 11a to produce a semiconductor device 20, a solder fillet (side fillet) 12 exposed on the side face of the semiconductor package 10 is formed between the end face through hole electrodes 1b and electrodes and wiring patterns on the mounting substrate 11. The formation of the solder fillet 12 provides effects that the examination of the mounted state from the external appearance becomes easy and that the strength of the mounting also increases.

On the other hand, referring to FIG. 5, a semiconductor package 50 according to the comparative example does not has a end face through hole electrode and merely has outer electrodes 51a formed around openings of outer through holes 51 and inner electrodes 52a formed around openings of inner through holes 52. Therefore, when the semiconductor package 50 is mounted on a mounting substrate 61 by a mounting solder 61a to produce a semiconductor device 60, no solder fillet exposed on a side face of the semiconductor package 50 can be formed between the semiconductor package 50 and the mounting substrate 61. Accordingly, the semiconductor package 50 according to the comparative example can not obtain the effects of the present invention, described above.

Next, one example for the steps of forming the end face through hole, the inner through hole and so on of the semiconductor package according to the example of the present invention is explained.

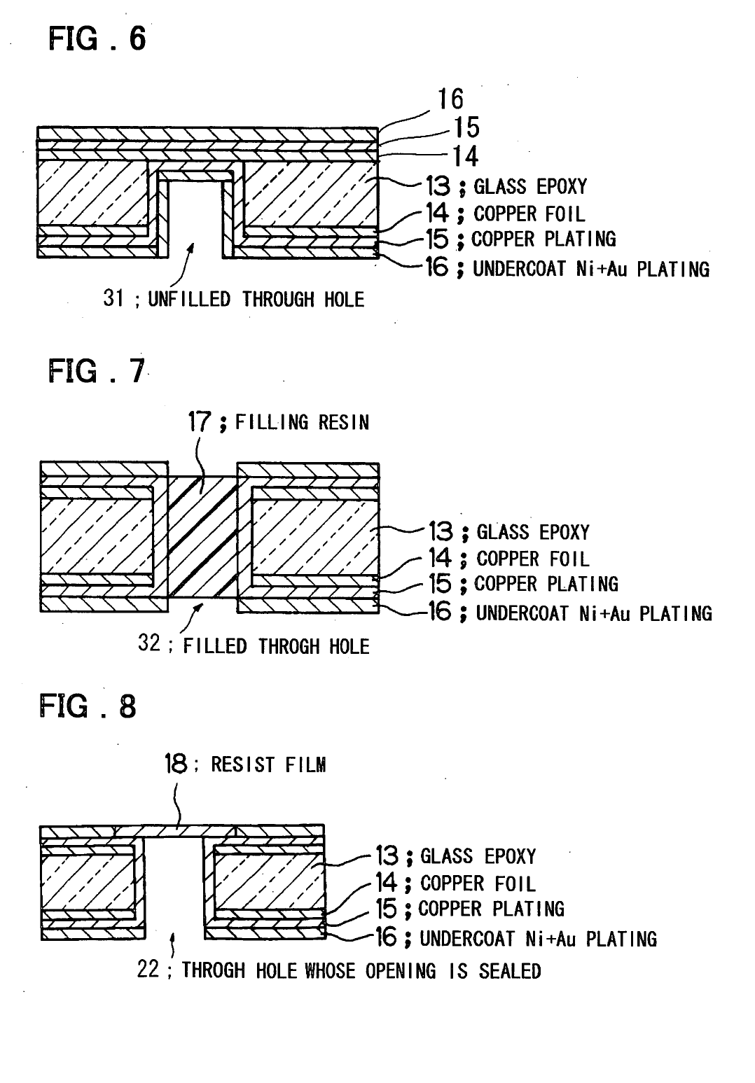

FIG. 6 is a figure to explain a method for forming the unfilled through hole of the interposer substrate, which serves as the end face through hole of the semiconductor package according to the example of the present invention, and the electrode around the through hole.

(A1) Referring to FIG. 6, a laser beam is applied to a glass epoxy substrate 13, which is a base material for an interposer substrate and of which copper films (foils) are formed on both the sides, from the back side of the substrate 13, which serves as the back side of the package, to form a non-penetration hole. At this time, a copper foil 14 on the top side of the substrate 13, which serves as the top side of the package, is left.

(A2) Copper platings 15 are plated on the entire surface of the substrate 13. At this time, the inside of an unfilled through hole 31 is also coated with the copper plating 15.

(A3) The copper plating 15 and copper foil 14 on the substrate 13 are etched to form a pattern wiring.

(A4) An undercoat nickel plating and gold plating 16 are plated on the pattern wiring formed by etching the copper plating 15 and copper foil 14. An electrode which serves as the end face through hole electrode of the semiconductor package is therefore formed inside the unfilled through hole 31, and a land which serves as the outer electrode is also formed around the opening of the unfilled through hole 31.

FIG. 7 is a figure to explain a method for making the filled through hole of the interposer substrate, which serves as the inner through hole of the semiconductor package according to the example of the present invention, and the electrode around the through hole.

(B1) Referring to FIG. 7, the glass epoxy substrate 13 described above is bored by, e.g., using a drill.

(B2) A plating step is performed simultaneously with the above step (A2), and the inside of a through hole 32 to be filled is also coated with the copper plating 15.

(B3) An etching step is performed simultaneously with the above step (A3).

(B4) The through hole 32 is filled with a filling resin 17 to form the filled through hole 32.

(B5) The undercoat nickel plating and gold plating 16 are plating on the pattern wiring formed by etching the copper plating 15 and copper foil 14. A land which serves as the inner electrode is therefore formed around the opening of the filled through hole 32.

FIG. 8 is a figure to explain a method for making the through hole whose opening is sealed at one side of the interposer substrate and which serves as the inner through hole of the semiconductor package according to another example of the present invention, and the electrode around the through hole.

In an example shown in FIG. 8, a through hole 22 whose opening is sealed at one side (opening end), in place of the filled through hole 32 shown in FIG. 7, is formed as the inner through hole of the semiconductor package. In place of the resin-filling step in the step (B4) among the above steps (B1)-(B5), the opening at the top side of the through hole 22 is sealed and covered with a resist film 18. The resist film 18 also can prevent disadvantage, such as a short circuit by a solder, in the mounting time.

It should be noted that other object s, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

1. An interposer substrate,
wherein a plurality of semiconductor chips are mounted on one side of the interposer substrate,
a plurality of product patterns are laid out in an array on the other side of the interposer substrate, and
each divided part of the interposer substrate is used as a component of a semiconductor package,
the interposer substrate comprising:
a plurality of unfilled outer through holes, which are arrayed at predetermined positions so as to serve as end face through holes arrayed at a periphery of said semiconductor package when said semiconductor package is formed;
a plurality of inner through holes, which are arrayed at an area surrounded by said outer through holes so as to serve as through holes arrayed inside of said semiconductor package when said semiconductor package is formed;
a plurality of first electrodes, which are each formed inside said outer through holes so as to serve as end face through hole electrodes exposed on a side face of said semiconductor package when the interposer substrate is cut across said outer through holes; and
a plurality of second electrodes, which are each formed around openings of said inner through holes on the other side of the interposer substrate so as to serve as inner electrodes of said semiconductor package.

2. The interposer substrate as defined in claim 1,
wherein a solder fillet is formed between said end face through hole electrode and a mounting substrate when the other side of the interposer substrate is soldered on said mounting substrate to mount said semiconductor package on said mounting substrate.

3. The interposer substrate as defined in claim 1,
wherein the interposer substrate has a plurality of outer electrodes each formed around openings of said end face through holes on the other side of the interposer substrate.

4. The interposer substrate as defined in claim 1,
wherein said inner through holes are filled with a resin.

5. The interposer substrate as defined in claim 1,
wherein said openings of said inner through holes are sealed at least at one side of the interposer substrate.

6. The interposer substrate as defined in claim 1,
wherein transverse cross sections of said outer through holes are ellipse in shape.

7. A semiconductor package comprising:
a semiconductor chip; an interposer substrate; a plurality of electrodes; a plurality of unfilled end face through holes; and
a plurality of inner through holes;
wherein said semiconductor chip is mounted on one side of said interposer substrate,
said electrodes are laid out in an array on the other side of said interposer substrate,
said unfilled end face through holes are arrayed along the periphery of the semiconductor package,
said inner through holes are arrayed along an inner area of the semiconductor package,
a plurality of end face through hole electrodes of said electrodes are each formed inside said end face through holes so as to be exposed on a side face of the semiconductor package, and
a plurality of inner electrodes of said electrodes are each formed around openings of said inner through holes on the other side of said interposer substrate.

8. The semiconductor package as defined in claim 7,
wherein said end face through holes are formed by dicing and dividing said interposer substrate so as to expose said end face through hole electrode.

9. The semiconductor package as defined in claim 7,
wherein a solder fillet is formed between said end face through hole electrode and a mounting substrate on a side part of the semiconductor package when the other side of said interposer substrate is soldered on said mounting substrate to mount the semiconductor package on said mounting substrate.

10. The semiconductor package as defied in claim 7,
wherein the semiconductor package has a plurality of outer electrodes each formed around openings of said end face through holes on the other side of said interposer substrate.

11. The semiconductor package as defined in claim 7,
wherein said inner through holes are filled with a resin.

12. The semiconductor package as defined in claim 7,
wherein said openings of said inner through holes are sealed at least at one side of said interposer substrate.

13. The semiconductor package as defined in claim 7,
wherein transverse cross sections of said end face through holes are ellipse in shape.

14. A semiconductor package comprising:
a semiconductor chip; a plurality of electrodes; and a plurality of unfilled end face through holes;
wherein said semiconductor chip is mounted on one side of the semiconductor package,
said electrodes are arrayed in an array on the other side of the semiconductor package,
said unfilled end face through holes are arrayed at the periphery of the semiconductor package; and
a plurality of end face through hole electrodes of said electrodes are each formed inside said end face through holes so as to be exposed on a side face of the semiconductor package.

15. A semiconductor device comprising:
a semiconductor package comprising a semiconductor chip and an interposer substrate, said semiconductor chip being mounted on one side of said interposer substrate, a plurality of electrodes being laid out in an array on the other side of said interposer substrate;
a mounting substrate for mounting said semiconductor package;
a plurality of unfilled end face through holes arrayed at the periphery of said semiconductor package;
a plurality of inner through holes arrayed at an inner area of said semiconductor package;
a plurality of end face through hole electrodes, which are each formed inside said end face through holes so as to be exposed on a side face of said semiconductor package;
a plurality of inner electrodes, which are each formed around openings of said inner through holes on the other side of said interposer substrate; and
a solder fillet formed between said end face through hole electrode and said mounting substrate on a side part of said semiconductor package.

16. The semiconductor device as defined in claim 15,
wherein said end face through holes are formed by dicing and dividing said interposer substrate so as to expose said end face through hole electrode.

17. The semiconductor device as defined in claim 15,
wherein the semiconductor device has a plurality of outer electrodes each formed around openings of said end face through holes on the other side of said interposer substrate.

18. The semiconductor device as defined in claim 15,
wherein said inner through holes are filled with a resin.

19. The semiconductor device as defined in claim 15,
wherein said openings of said inner through holes are sealed at least at one side of said interposer substrate.

20. The semiconductor device as defined in claim 15,
wherein transverse cross sections of said end face through holes are ellipse in shape.

21. A method for producing an interposer substrate wherein
a plurality of semiconductor chips are mounted on one side of the interposer substrate, a plurality of product patterns are laid out in an array on the other side of the interposer substrate, and the interposer substrate serves as a component of a semiconductor package by dividing into pieces;
the method comprising the steps of:
forming a plurality of penetration holes in a base material, of which electrically conductive layers are formed on both sides, by mechanical processing;
forming a plurality of non-penetration holes around said penetration holes in said base material by laser processing;
forming first electrodes at least inside said non-penetration holes by plating said penetration holes and non-penetration holes, and dicing and dividing said non-penetration holes so as to serve as end face through hole electrodes of said semiconductor package;
forming a plurality of at least second electrodes in an array on said base material by etching said electrically conductive layer; and
filling said plated penetration holes or sealing openings of said penetration holes at least on one side of the interposer substrate.

22. A method for producing a semiconductor package;
the semiconductor package having a plurality of semiconductor chips and an interposer substrate,
the method comprising the steps of:
providing an interposer substrate, said interposer substrate serving as a component of the semiconductor package by mounting said semiconductor chips on one side of said interposer substrate, laying out a plurality of electrodes in an array on the other side of said interposer substrate and dividing said interposer substrate into pieces,
said interposer substrate comprising;
a plurality of unfilled outer through holes arrayed at predetermined positions,
a plurality of inner through holes, which are arrayed at an area surrounded by said outer through holes, and which are filled or whose openings are sealed at least on one side of said interposer substrate,
a plurality of first electrodes, which are each formed inside said outer through holes so as to serve as end face through hole electrodes exposed on a side face of said semiconductor package,
a plurality of outer electrodes, which are each formed around openings of said outer through holes on the other side of the interposer substrate, and
a plurality of second electrodes, which are each formed around openings of said inner through holes on the other side of the interposer substrate so as to serve as inner electrodes of said semiconductor package;
mounting said semiconductor chips on said one side of said interposer substrate;
connecting said semiconductor chips with said interposer substrate electrically;
sealing said semiconductor chips on said interposer substrate; and
forming said end face through hole electrodes exposed on said side face of the divided semiconductor package, by dicing said interposer substrate across said outer through holes, and dividing the semiconductor package into pieces so as to serve said outer through holes of said interposer substrate as said end face through holes of the divided semiconductor package.

23. A method for producing a semiconductor device;
the semiconductor device comprising a semiconductor package and a mounting substrate for mounting said semiconductor package;
the method comprising the steps of:
providing a semiconductor package comprising;
a semiconductor chip,
an interposer substrate, said semiconductor chip being mounted on one side of said interposer substrate, a plurality of electrodes being laid out in an array on the other side of said interposer substrate,
a plurality of unfilled end face through holes, which are each arrayed at the periphery of said semiconductor package,
a plurality of inner through holes, which are each arrayed in an inner area of said semiconductor package,
a plurality of end face through hole electrodes, which are each formed inside said end face through holes so as to be exposed on a side face of said semiconductor package,
a plurality of outer electrodes of said electrodes, which are each formed around openings of said end face through holes on the other side of said interposer substrate, and
a plurality of inner electrodes, which are each formed around openings of said inner through holes on the other side of said interposer substrate;
the method further comprising the steps of:
forming a solder fillet between said end face through hole electrode and said mounting substrate in the side face of said semiconductor package when the other side of said interposer substrate is soldered on said mounting substrate to mount said semiconductor package on said mounting substrate.
